(19) United States
(12) Patent Application Publication
(10) Pub. No.: US 2015/0236240 A1
(43) Pub. Date: Aug. 20, 2015

(54) PIEZOELECTRIC VIBRATION ACTUATOR AND METHOD OF MANUFACTURING THE SAME

(71) Applicant: SAMSUNG ELECTRO-MECHANICS CO., LTD., Gyeonggi-Do (KR)

(72) Inventor: Sung Chan PARK, Gyeonggi-Do (KR)

(73) Assignee: SAMSUNG ELECTRO-MECHANICS CO., LTD., Gyeonggi-Do (KR)

(21) Appl. No.: 14/609,486

(22) Filed: Jan. 30, 2015

(30) Foreign Application Priority Data
Feb. 18, 2014 (KR) 10-2014-0018585

(51) Int. Cl. H01L 41/09; H01L 41/25; H01L 41/053

(52) U.S. Cl. CPC H01L 41/09; H01L 41/053; H01L 41/25

(57) ABSTRACT

Embodiments of the invention provide a piezoelectric vibration actuator and a method of manufacturing the same. According to at least one embodiment, the piezoelectric vibration actuator includes a case having an internal space partitioned into a top wall, a right side wall, a bottom wall, and a left side wall and having opened one side wall, and a driving part coupled to the case and linearly translated toward the top wall and the bottom wall in the internal space of the case.

### CROSS REFERENCE TO RELATED APPLICATION

This application claims the benefit of and priority under 35 U.S.C. §119 to Korean Patent Application No. KR 10-2014-0018585, entitled “PIEZOELECTRIC VIBRATION ACTUATOR AND METHOD OF MANUFACTURING THE SAME,” filed on Feb. 18, 2014, which is hereby incorporated by reference in its entirety into this application.

### BACKGROUND

1. Field of the Invention

The present invention relates to a piezoelectric vibration actuator and method of manufacturing the same.

2. Description of the Related Art

Generally, in a portable electronic apparatus, such as a portable phone, an E-book terminal, a game machine, a portable multimedia player (PMP), for example, a vibration function has been utilized for various uses.

Particularly, a vibration generating apparatus for generating the vibration has been mainly mounted in the portable electronic apparatus to thereby be used as an alert function, which is a soundless receiving signal.

In accordance with multi-functionalization of the portable electronic apparatus, miniaturization, integration, and multi-functionalization of the vibration generating apparatus have been currently demanded.

Recently, a touch type apparatus performing an input by touching the portable electronic apparatus depending on a demand of a user that is to simply and conveniently use the portable electronic apparatus has been generally adopted in the portable electronic apparatus, and a haptic module, which is a kind of haptic interface, may be used so that the user may more easily and conveniently perform communication with a computer or a program. A concept of terms ‘haptic’ meaning “tactile sense perception” widely includes a concept of reflecting user's intuitive experience on an interface to diversify feedback for a touch, in addition to a concept of performing an input through a touch.

Korean Patent Laid-Open Publication No. 10-2013-0125170 generally relates to the conventional art and suggests a piezoelectric vibration module including a vibration plate flex-vibrating in a vertical direction within an internal space formed by an upper case and a lower case. The piezoelectric vibration module according to the conventional art includes the upper case having a shape of a box of which a lower surface is opened and the lower case covering the opened lower surface to define the internal space of the piezoelectric vibration module.

Since the piezoelectric vibration module described in Korean Patent Laid-Open Publication No. 10-2013-0125170 according to the conventional art linearly vibrates in the vertical direction to transfer vibration force to the outside, the opened lower surface of the upper case is formed to correspond to a vibration direction of the vibration plate including a piezoelectric element, which may have an influence on cohesion between the upper case and the lower case through continuously flex vibration. In the case in which the upper case and the lower case are decoupled from each other, the flex-vibrating piezoelectric element and the vibration plate may be exposed to the outside. As well known to those skilled in the art, the piezoelectric element is easily broken due to strong brittleness. Therefore, a role of a case is very important in order to prevent a contact or collision with the outside.

### SUMMARY

Accordingly, embodiments of the invention have been made to provide a piezoelectric vibration actuator in which an opened wall of a case is formed in a direction different from a linear translation direction of a vibration plate to ensure vertical translation of the vibration plate on which a piezoelectric element is stacked in the case.

According to at least one embodiment, a piezoelectric vibration actuator includes a case having an internal space partitioned into a top wall, a right side wall, a bottom wall, and a left side wall and having opened one side wall, and a driving part coupled to the case and linearly translated toward the top wall and the bottom wall in the internal space of the case. According to at least one embodiment, the opened one side wall of the case is formed as a side wall regardless of a flex-vibration direction of the driving part.

According to at least one embodiment, the opened one side wall of the case is covered with a cover member to allow the piezoelectric vibration actuation not to be affected by an external environment.

According to at least one embodiment, the case is formed in a shape of a rectangular frame of which a front side wall and a rear side wall opposing the front side wall are opened. According to at least one embodiment, the opened front and rear side walls is also closed by the cover member.

Unlike this, according to at least one embodiment, the case is designed in a shape of a box of which only the front side wall is opened, such that the piezoelectric vibration actuator is closed by one cover member.

According to at least one embodiment, the case includes one or more through-holes formed in the right side wall and the left side wall thereof.

According to at least one embodiment, the driving part includes a vibration plate that is flat, leg parts that are bent downwardly from both end portions of the vibration plate, and a piezoelectric element that is disposed on one surface of the vibration plate or the other surface thereof opposing one surface.

According to at least one embodiment, a distance between the leg parts is the same as a distance between the right side wall and the left side wall of the case. Therefore, the leg parts are disposed to contact the right side wall and the left side wall of the case in parallel with the right side wall and the left side wall of the case, and the driving part is fitted in a length direction of the case to maintain coupling between the case and the driving part even in a provisional assembly state.

According to at least one embodiment, the uppermost end portions of the through-holes are formed at a position lower than that of the vibration plate so that the through-holes are closed by the leg parts of the driving part.

Adhering parts are formed in the through-holes in various schemes in order to couple the case and the leg parts of the driving part exposed through the through-holes of the case to each other.

In addition, the driving part further includes a frequency correcting part disposed adjacently to both end portions of the vibration plate or the driving part to adjust a resonant frequency of the vibration plate. According to at least one embodiment, the frequency correcting part limits a flux range of the vibration plate.

Additionally, the vibration plate includes a pair of supports installed in a vertical direction at both side edges thereof, and a weight body is disposed between the pair of supports.

According to at least another embodiment of the invention, a method of manufacturing a piezoelectric vibration actuator includes preparing a case of which one side wall is opened, preparing a driving part linearly translated in an internal space of the case through repeated expansion and contraction of a piezoelectric element, seating the driving part in the internal space of the case, and covering the opened one side wall of the case with a cover member.

According to at least one embodiment, the method of manufacturing a piezoelectric vibration actuator further includes, between the seating of the driving part and the covering of the opened one side wall of the case with the cover member, adjusting a resonant frequency of the driving part, wherein the adjusting of the resonant frequency of the driving part is repeatedly performed several times.

According to at least one embodiment, the driving part includes a vibration plate that is flat, leg parts that are bent downwardly from both end portions of the vibration plate, and the piezoelectric element that is disposed on the vibration plate.

According to at least one embodiment, the case has an internal space partitioned into a top wall, a right side wall, a bottom wall, a left side wall, and a rear side wall and have an opened front side wall.

According to at least one embodiment, the case includes one or more through-holes formed in the right side wall and the left side wall thereof.

According to at least one embodiment, the uppermost end portions of the through-holes is formed at a position lower than that of the vibration plate so that the through-holes are closed by the leg parts of the driving part.

Adhering parts are formed in the through-holes in various schemes, specifically, a welding scheme, in order to couple the case and the leg parts of the driving part exposed through the through-holes of the case to each other.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a perspective view of a piezoelectric vibration actuator according to an embodiment of the invention.

FIG. 2 is a view showing an inner portion of the piezoelectric vibration actuator from which a cover member is separated according to an embodiment of the invention.

FIG. 3 is an exploded perspective view of the piezoelectric vibration actuator shown in FIG. 1 according to an embodiment of the invention.

FIG. 4 is a view showing a piezoelectric vibration actuator according to another embodiment of the invention in a state in which a driving part that is to be disposed in an internal space is excluded.

FIG. 5 is a flow chart showing a method of manufacturing a piezoelectric vibration actuator according to an embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

Hereinafter, a piezoelectric vibration actuator and a method of manufacturing the same according to various embodiments of the invention will be described in detail with reference to the accompanying drawings.

According to at least one embodiment, there is provided a piezoelectric vibration actuator 1 capable of transferring vibration force of a piezoelectric element to an external component through repeated contraction and expansion.

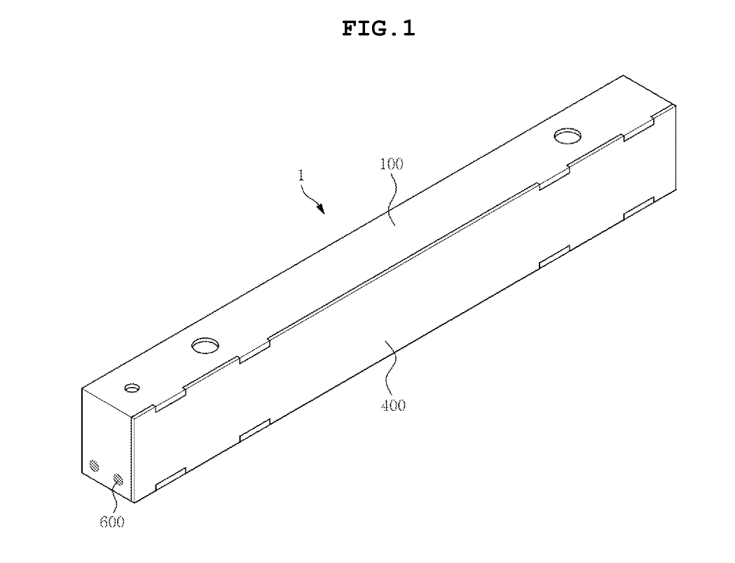

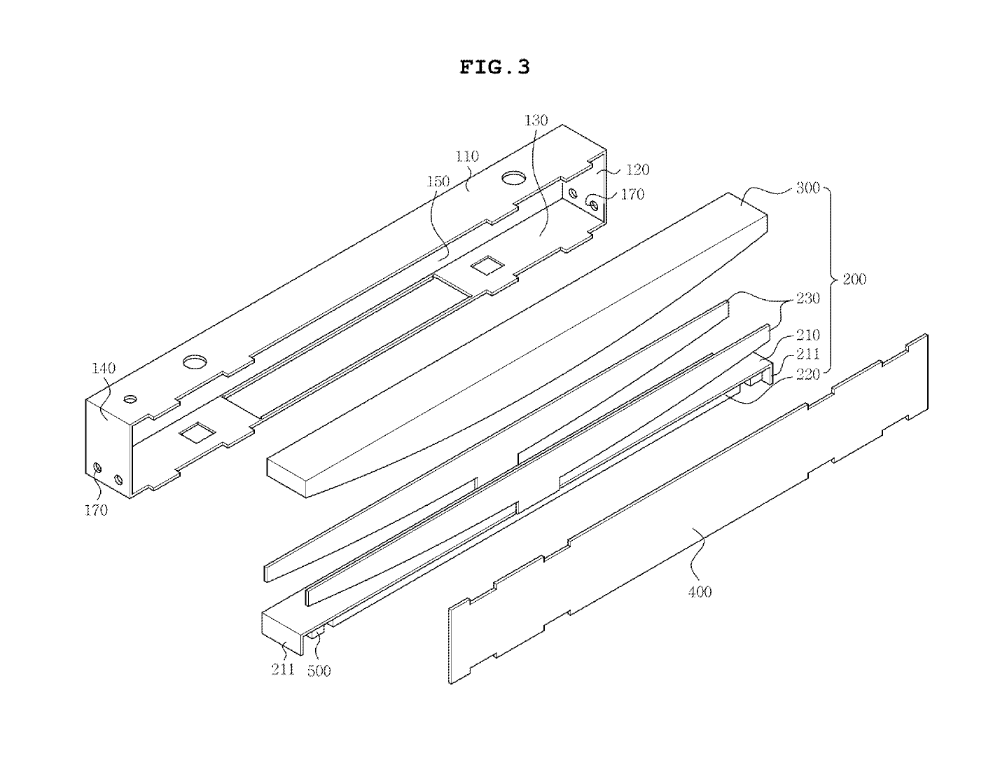

Referring to FIGS. 1 to 3, the piezoelectric vibration actuator 1 according to at least one embodiment, which is a means generating vibration force in a touch screen panel (not shown), for example, is enclosed by a case 100 and a cover member 400, and includes a driving part 200 disposed therein, wherein the driving part 200 flex-vibrates in a vertical direction depending on application of power through a printed circuit board (not shown). The piezoelectric vibration actuator 1 according to at least one embodiment further includes a weight body 300 disposed in an internal space thereof.

According to at least one embodiment, the case 100 has a shape of an elongated rectangular box of which one side wall (for example, a front side wall) is opened and accommodates the driving part 200, in other words, a piezoelectric element 220 and a vibration plate 210, in an internal space thereof.

As shown, the case 100 has a top wall 110, a bottom wall 130 opposing the top wall 110, a right side wall 120, a left side wall 140 opposing the right side wall 120, and a rear side wall 150, and is formed as a single component to improve durability of the piezoelectric vibration actuator 1. According to at least one embodiment, the case 100 is characterized in that the front side wall opposing the rear side wall 150 is opened. The driving part 200 is mounted in the case 100 to linearly vibrate (be translated) toward the top wall 110 and the bottom wall 130 of the case 100. The opened one side wall is formed in a direction different from a vibration direction of the driving part 200 linearly and flex-vibrating in the vertical direction, thereby making it possible to minimize a warpage phenomenon of the case 100 through the translation of the driving part 200.

According to at least one embodiment, the opened front side wall of the case 100 is covered with the cover member 400 generally having an elongated flat shape to close the internal space of the case 100. The cover member 400 is formed at a size and in a shape at which and in which it may close the opened front side wall of the case 100.

According to at least one embodiment, the case 100 and the cover member 400 are coupled to each other in various schemes, such as a caulking scheme, a welding scheme, and a bonding scheme, for example, well-known to those skilled in the art.

According to at least one embodiment, the piezoelectric vibration actuator 1 according to at least one embodiment is operated by the driving part 200 generating vibration force through translation of the piezoelectric element 220 repeatedly expanding and contracting in the vertical direction by external power applied thereto.

As shown, the driving part 200 includes the vibration plate 210 and the piezoelectric element 220. The driving part 200 is electrically connected to the printed circuit board applying the power for driving the piezoelectric element 220. Here, in order to assist in the clear understanding the various embodiments of the invention, a description for wirings between the piezoelectric element 220 and the printed circuit board (not shown) will be omitted.

In the case in which the power is applied to the piezoelectric element 220 through the printed circuit board, the piezoelectric element 220 is completely attached to the vibration plate 210, such that a moment is generated based on a central portion of the vibration plate 210 through a process in which the piezoelectric element 220 expands and/or contracts. Since the moment is generated in a state in which the vibration plate 210 is fixed to the right side wall 120 and the left side wall 140, flex-deformation occurs in the vertical direction at the central portion of the vibration plate 210. It is preferable that the vibration plate 210 is disposed to be upwardly spaced apart from the bottom wall 130 by a predetermined interval (in consideration of displacement of the vibration plate) in order to prevent collision between the piezoelectric element 220 and the bottom wall 130 due to the displacement of the vibration plate 210 in the vertical direction. As well known to those skilled in the art, the piezoelectric element 220 according to at least one embodiment of the invention is made of various materials, particularly, polymer and ceramic, as non-limiting examples.

In addition, the piezoelectric element 220 according to at least one embodiment is configured in a single layer type or is configured to be stacked in a multilayer type. The piezoelectric element stacked in the multilayer type secures an electric field required for driving the piezoelectric element even at a low external voltage. Therefore, it is preferable that the piezoelectric element stacked in the multilayer type is adopted according to at least one embodiment of the invention, since a decrease effect of a driving voltage of the piezoelectric vibration actuator according to at least one embodiment may be accomplished.

According to at least one embodiment, the vibration plate 210, which repeatedly expands and contracts integrally with the piezoelectric element 220 to transfer the vibration force of the piezoelectric element 220 to an external component, generally has a flat plate shape. The vibration plate 210 has the piezoelectric element 220 mounted on flat one surface thereof, and has the weight body 300 additionally mounted or disposed on the other surface thereof.

According to at least one embodiment, the vibration plate 210 is made of a metal material having elastic force, for example, SUS, so that it is deformed integrally with the piezoelectric element 220 repeatedly expanding and contracting by the external power applied thereto through the printed circuit board. In addition, the vibration plate 210 is also made of invar, which is a material having a coefficient of thermal expansion similar to that of the piezoelectric element, in order to prevent a bending phenomenon that occurs due to hardening of an adhering member in the case in which the vibration plate 210 and the piezoelectric element 220 are coupled to each other in a bonding coupling scheme.

As described above, the vibration plate 210 is made of the invar having the thermal expansion coefficient similar to that of the piezoelectric element 220. Therefore, since thermal stress generated in the piezoelectric element 220 at the time of operation or thermal impact under a high temperature external environment is decreased, a piezoelectric deterioration phenomenon that electrical characteristics are deteriorated is prevented.

According to at least one embodiment, the driving part 200 has the weight body 300 additionally mounted on the vibration plate 210 thereof, as described above. A position of the weight body 300 is fixed between a pair of supports 230 disposed in parallel with each other at both side edges of the vibration plate 210 and standing up in the vertical direction. The supports 230 are coupled to a central portion of the vibration plate 210. The vibration plate 210 and the support 230 are formed of an integral signal component or be fixed and coupled to each other in various bonding schemes.

According to at least one embodiment, the weight body 300, which is a medium increasing the vibration force of the driving part 200 as much as possible, is formed to be inclined upwardly from a central portion thereof toward both end portions thereof in order to prevent a contact with the vibration plate 210, as shown. As described above, since the weight body 300 does not contact the vibration plate 210, the piezoelectric element 220 is also disposed on the other surface of the vibration plate 210 that is flat. In addition, in the piezoelectric vibration actuator 1 according to at least one embodiment the case 100 is disposed to be spaced apart from an upper portion of the weight body 300, such that a contact or collision between the weight body 300 and an inner portion of the top wall 110 of the case 100 during driving displacement of the vibration plate 210 that is bent in an upward direction is prevented. For reference, the weight body 300 is made of a metal material, preferably, a tungsten material having relatively high density in the same volume.

According to at least one embodiment, the vibration plate 210 of the driving part 200 is spaced apart from the bottom wall 130 of the case 100 by a predetermined interval in a state in which it is in parallel with the bottom wall 130 of the case 100 and preferably includes leg parts 211 perpendicularly bent downwardly at both end portions thereof, such that a space is formed between the bottom wall 130 of the case 100 and the vibration plate 210. According to at least one embodiment, a contact or collision between the driving part 200 and the bottom wall 130 during driving displacement of the vibration plate 210 that is bent downwardly is prevented through the space between the vibration plate 210 of the driving part 200 and the bottom wall 130.

According to at least one embodiment, the vibration plate 210 includes two leg parts 211 spaced apart from each other and facing each other. Here, a distance between the two leg parts 211 is preferably maintained to be the same as a distance between the right side wall 120 and the left side wall 140 of the case 100. In this case, both end portions of the vibration plate 210 are fitted between the right side wall 120 and the left side wall 140 in a horizontal direction through the opened front side wall of the case to assist in selection of positions of the case 100 and the driving part 200 at the time of performing assembling. However, various embodiments of the invention are not limited thereto. Thus, the distance between the two leg parts 211 are shorter than the distance between the right side wall 120 and the left side wall 140.

Preferably, the case 100 includes one or more through-holes 170 each perforated in the right side wall 120 and the left side wall 140 thereof. Portions of the leg parts 211 of the vibration plate 210 are exposed to the outside through the through-holes 170 of the case 100. Therefore, a worker may form adhering parts 600 along contact circumferences between the through-holes 170 and the leg parts 211, fill the adhering parts 600 in spaces defined by the through-holes 170 and the leg parts 211, or perform welding.

According to at least one embodiment, the adhering part 600, which is a medium member coupling the case 100 and the vibration plate 210 disposed in a length direction of the case to each other, fixes the case 100 and the vibration plate 210 to each other in a bonding scheme or a welding scheme, as non-limiting examples.

In the piezoelectric vibration actuator 1 according to at least one embodiment of the invention a perforation height of the through-hole 170 needs to be limited so that a height from an upper portion of the bottom wall 130 to the uppermost end portion of the through-hole 170 is maintained to be lower than a height from the upper portion of the bottom wall 130 to the vibration plate 210, in order to form the adhering part 600 as described above. Preferably, the through-hole 170 needs to be formed so that the uppermost end portion thereof is lower than the vibration plate 210.

When the through-holes 170 are perforated in the right side wall 120 and the left side wall 140 so that the lowermost end portions thereof are higher than a height of the vibration plate 210, the through-holes 170 and the leg parts 211 do not have a overlapped region therebetween, such that they are not fixed to each other by the adhering parts 600. Unlike this, when the vibration plate 210 is disposed between the uppermost end portions and the lowermost end portion of the through-holes 170, the adhering parts 600 are coated on the flat surface of the vibration plate 210 to have an influence on a resonant frequency of the driving part 200.

As described above, according to at least one embodiment, one side wall (front side wall) of the case is opened, thereby making it possible to assist in assembling the driving part 200 and the case 100 to each other before the case is finishing-treated by the cover member and directly confirm and control a resonant frequency and an operation of the driving part 200 with the naked eyes after the driving part 200 is mounted in the case 100.

According to at least one embodiment, this control is implemented by attaching a frequency correcting part 500 to one surface of the vibration plate 210 in a welding scheme, for example. Preferably, the frequency correcting part 500 is made of the same material as that of the vibration plate 210 in order to minimize thermal impact due to high heat generated at the time of being welded with the vibration plate 210.

According to at least one embodiment, in a haptic device (for example, a cellular phone or other portable apparatuses) to which the piezoelectric vibration actuator is applied, a use frequency is adjusted during assembly. Generally, a frequency that provides haptic sensation is 300 Hz or, preferably approximately 150 to 250 Hz, and more preferably, 200 Hz.

According to at least one embodiment, a correlation between the vibration plate 210 and the frequency that provides the haptic sensation as described above is inferred from the following Mathematical Equations.

$${F}_{n} = \sqrt{\frac{k}{m}} \qquad [ Mathematical Equation 1 ]$$

Here, Fₙ indicates a resonant frequency, k indicates rigidity of the driving part, and m is a mass of the driving part. A terms ‘driving part’, which is a component translated in the vertical direction by power applied thereto in the piezoelectric vibration module according to at least one embodiment of the invention to generate vibration force, means the vibration plate 210, the weight body 300, or the piezoelectric element 220, for example.

$$k ∝ C \times \frac{EI}{{L}^{3}} \qquad [ Mathematical Equation 2 ]$$

Here, k indicates rigidity of the driving part, C indicates a constant, E indicates a Young's modulus, I indicates a moment of inertia, and L indicates an effective length.

Based on Mathematical Equation 2, the rigidity k of the driving part becomes small as a length of the vibration plate 210 becomes long. When this result is substituted in Mathematical Equation 1, it may be appreciated that a resonant frequency Fₙ is decreased as the rigidity k of the driving part becomes small.

As the length of the vibration plate 210 becomes long, the resonant frequency Fₙ is decreased. As a result, the length of the vibration plate 210 is a factor having a very large influence on the use resonant frequency. As described above, an actual flux range (length) of the vibration plate 210 is adjusted through the frequency correcting part 500, and this process is performed until the case 100 is finished by the cover member 400.

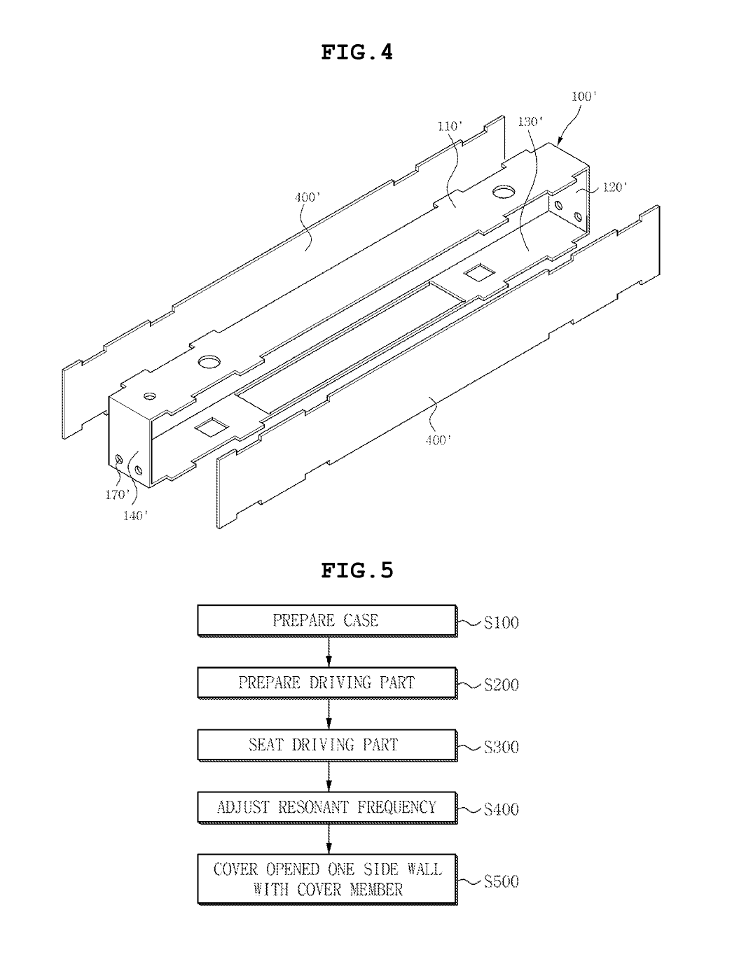

FIG. 4 is a view showing a piezoelectric vibration actuator according to another embodiment of the invention in a state in which a driving part that is to be disposed in an internal space is excluded. A case 100′ according to another embodiment of the invention is similar to or is the same as the case 100 of the piezoelectric vibration actuator 1 according to an exemplary embodiment of the present disclosure shown in FIGS. 1 to 3 except for a shape thereof. Therefore, in order to assist in clearly understanding the present disclosure, a description for components that are the same as or similar to the above-mentioned components will be omitted.

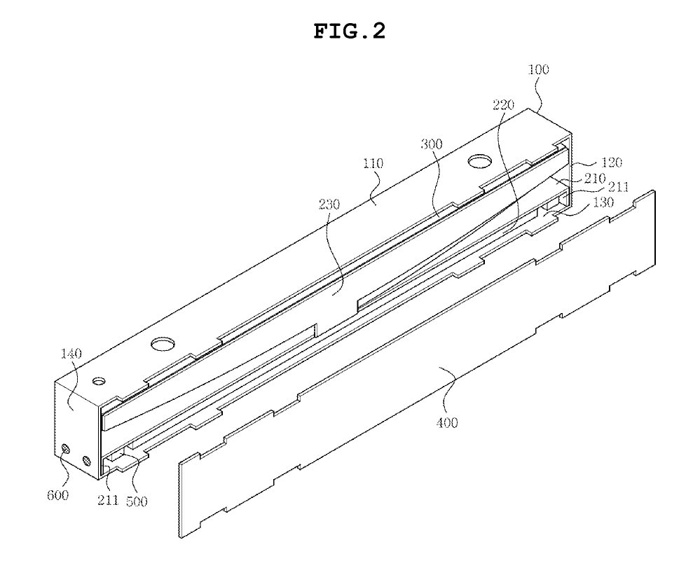

Referring to FIG. 4, the case 100′ has a shape of a rectangular frame of which both side walls (for example, front and rear side walls) opposing each other are opened and accommodates the driving part 200 (See FIG. 2) in an internal space thereof.

As shown, the case 100′ has a top wall 110′, a bottom wall 130′ opposing the top wall 110′, a right side wall 120′, and a left side wall 140′ opposing the right side wall 120′. In accordance with another embodiment, the case 100′ is characterized in that a rear side wall and a front side wall opposing the rear side wall are opened.

According to at least one embodiment, the opened rear and front side walls of the case 100′ is covered with a cover member 400′ generally having an elongated flat shape to define the internal space of the case 100′. The cover member 400′ is formed at a size and in a shape at which and in which it closes each of the opened rear and front side walls of the case 100′.

In addition, the case 100′ includes one or more through-holes 170′ each perforated in the right side wall 120′ and the left side wall 140′ thereof.

FIG. 5 is a flow chart showing a method of manufacturing a piezoelectric vibration actuator according to at least one embodiment of the invention.

According to at least one embodiment, the method of manufacturing a piezoelectric vibration actuator includes preparing the case 100 (See FIG. 2) of which the front side wall is opened and the top wall, the right side wall, the bottom wall, the left side wall, and the rear side wall are partitioned (S100). The driving part 200 is mounted in the internal space of the case 100 enclosed by five walls. The driving part is later inserted in a horizontal direction based on the bottom wall into the internal space of the case having the above-mentioned structure, and an assembled state between the case and the driving part after the driving part is inserted is confirmed with the naked eyes.

Optionally, another type of case 100′ (see FIG. 4) is applied, wherein another type of case 100′ has the front and rear side walls that are opened, the top wall, the right side wall, the bottom wall, and the left side wall that are partitioned, and has the driving part 200 mounted in the internal space enclosed by the four walls.

Then, the method of manufacturing a piezoelectric vibration actuator according to at least one embodiment includes preparing the driving part having the position fixed within the case 100 and linearly translated toward the top wall and the bottom wall (S200).

Here, the driving part 200 includes the vibration plate that is flat, the leg parts that are bent downwardly from both end portions of the vibration plate, and the piezoelectric element that is disposed on one surface or the other surface of the vibration plate. The piezoelectric element repeatedly expands and contracts by the external power applied thereto to generate the vibration force in the driving part.

Preferably, the distance between the two leg parts is the same as the distance between the right side wall and the left side wall of the case. Therefore, the leg parts are disposed to contact the right side wall and/or the left side wall of the case and provide a predetermined space between the bottom wall and the vibration plate.

The method of manufacturing a piezoelectric vibration actuator according to at least one embodiment includes fixing the position of the driving part in the internal space of the case (S300). In S300, the driving part formed of the vibration plate having an inverse U shape is fitted between the right side wall and the left side wall of the case. The respective leg parts disposed at both end portions of the driving part are seated on the bottom wall simultaneously with being disposed to contact the right side wall and the left side wall in parallel with the right side wall and the left side wall.

Then, the adhering parts are formed in the through-holes of the case in various contact schemes (for example, a welding scheme). Therefore, both end portions of the driving part are fixed and coupled to the right side wall and the left side wall of the case.

The method of manufacturing a piezoelectric vibration actuator according to at least one embodiment includes covering the opened one side wall, specifically, the opened front side wall with the cover member (S500). As a result, the method of manufacturing a piezoelectric vibration actuator according to at least one embodiment is finished, thereby making it possible to protect the driving part linearly vibrating within the case.

Preferably, the method of manufacturing a piezoelectric vibration actuator according to at least one embodiment further includes, adjusting the resonant frequency of the vibration plate of the driving part (S400) before the covering of the opened one side wall with the cover member (S500). According to at least one embodiment, the frequency is adjusted to provide the haptic sensation required for the piezoelectric vibration actuator. According to at least one embodiment, this is performed after the driving part and the case are coupled to each other, such that frequencies are corrected to be appropriate for the respective piezoelectric vibration actuators, thereby making it possible to improve a yield. As a result, a production cost may be effectively decreased.

In addition, according to at least one embodiment, a driven state of the driving part is directly confirmed with the naked eyes before the case is completely closed by the cover member.

As set forth above, according to various embodiments of the invention, the piezoelectric vibration actuator having the internal space is provided to certainly secure the linear translation of the driving part flex-vibrating through the contraction and/or expansion of the piezoelectric element.

One side surface of the case other than the top wall, the bottom wall, the right side wall, and the left side wall of the case is opened, thereby making it possible to easily insert and assemble the driving part having the piezoelectric element stacked therein in the horizontal direction into the internal space of the case and directly confirm the driven part of the driving state with the naked eyes even after the driving part is mounted in the internal space of the case.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A piezoelectric vibration actuator, comprising:
a case comprising an internal space partitioned into a top wall, a right side wall, a bottom wall, and a left side wall and having opened one side wall; and
a driving part coupled to the case and linearly translated toward the top wall and the bottom wall in the internal space of the case.

2. The piezoelectric vibration actuator of claim 1, wherein the opened one side wall of the case is covered with a cover member.

3. The piezoelectric vibration actuator of claim 1, wherein front and rear side walls of the case are formed as the opened one side wall.

4. The piezoelectric vibration actuator of claim 1, wherein the case further comprises a rear side wall, and only a front side wall of the case is formed as the opened one side wall.

5. The piezoelectric vibration actuator of claim 1, wherein the case comprises one or more through-holes perforated in the right side wall and the left side wall thereof.

6. The piezoelectric vibration actuator of claim 1, wherein the driving part comprises a vibration plate that is flat, leg parts that are bent downwardly from both end portions of the vibration plate, and a piezoelectric element that is disposed on the vibration plate.

7. The piezoelectric vibration actuator of claim 6, wherein a distance between the leg parts is the same as a distance between the right side wall and the left side wall of the case.

8. The piezoelectric vibration actuator of claim 6, wherein the leg parts are disposed to contact the right side wall and the left side wall of the case in parallel with the right side wall and the left side wall of the case.

9. The piezoelectric vibration actuator of claim 5, wherein the through-holes are closed by the leg parts of the driving part.

10. The piezoelectric vibration actuator of claim 9, wherein the uppermost end portions of the through-holes are formed at a position lower than that of the vibration plate.

11. The piezoelectric vibration actuator of claim 5, wherein the through-holes couple the case and the leg parts to each other through adhering parts.

12. The piezoelectric vibration actuator of claim 1, wherein the driving part further comprises a frequency correcting part.

13. The piezoelectric vibration actuator of claim 12, wherein the frequency correcting part is provided adjacent to both end portions of the driving part.

14. The piezoelectric vibration actuator of claim 6, wherein the driving part further comprises a weight body that does not contact the vibration plate.

15. The piezoelectric vibration actuator of claim 6, wherein the vibration plate comprises a pair of supports installed in a vertical direction at both side edges thereof.

16. A method of manufacturing a piezoelectric vibration actuator, the method comprising:
preparing a case of which one side wall is opened;
preparing a driving part linearly translated in an internal space of the case through repeated expansion and contraction of a piezoelectric element;
seating the driving part in the internal space of the case; and
covering the opened one side wall of the case with a cover member.

17. The method of manufacturing a piezoelectric vibration actuator of claim 16, further comprising:
adjusting a resonant frequency of the driving part.

18. The method of manufacturing a piezoelectric vibration actuator of claim 16, wherein the driving part comprises a vibration plate that is flat, leg parts that are bent downwardly from both end portions of the vibration plate, and the piezoelectric element that is disposed on the vibration plate.

19. The method of manufacturing a piezoelectric vibration actuator of claim 16, wherein the case has an internal space partitioned into a top wall, a right side wall, a bottom wall, a left side wall, and a rear side wall and has an opened front side wall.

20. The method of manufacturing a piezoelectric vibration actuator of claim 19, wherein the case comprises one or more through-holes perforated in the right side wall and the left side wall thereof.

21. The method of manufacturing a piezoelectric vibration actuator of claim 18, wherein the leg parts are disposed to contact the right side wall and the left side wall of the case in parallel with the right side wall and the left side wall of the case.

22. The method of manufacturing a piezoelectric vibration actuator of claim 21, wherein the through-holes are closed by the leg parts of the driving part.

23. The method of manufacturing a piezoelectric vibration actuator of claim 22, wherein the through-holes couple the case and the leg parts to each other through adhering parts.

24. The method of manufacturing a piezoelectric vibration actuator of claim 23, wherein the adhering parts are formed in a welding scheme.
